(19) United States
(12) Patent Application Publication
(10) Pub. No.: US 2025/0304430 A1
(43) Pub. Date: Oct. 2, 2025

(54) ASYMMETRIC FILLER AS TEMPERATURE TRANSIENT FIX

(71) Applicant: Rosemount Aerospace Inc., Burnsville, MN (US)

(72) Inventors: David Potasek, Lakeville, MN (US); Roger Backman, Eagan, MN (US)

(21) Appl. No.: 19/092,688

(22) Filed: Mar. 27, 2025

Related U.S. Application Data
(60) Provisional application No. 63/571,776, filed on Mar. 29, 2024.

(51) Int. Cl. B81B 7/00; B81C 99/00

(52) U.S. Cl. CPC B81B 7/0019; B81C 99/004; B81B 2201/0264; B81B 2207/115; B81C 2201/112

(57) ABSTRACT

A system for reducing electromotive force (EMF) errors is disclosed. The system may include a circuit component with a plurality of leads soldered to a circuit board. The system may also include a filler material coupled to at least a first lead of the plurality of leads. The system may exhibit an asymmetrical thermal conduction of the first lead relative to a different lead of the plurality of leads due to the filler material.

### CROSS-REFERENCE TO RELATED APPLICATION

The present application claims the benefit under 35 U.S.C. § 119 (e) of U.S. Provisional Application Ser. No. 63/571,776, filed Mar. 29, 2024, entitled ASYMMETRIC FILLER AS TEMPERATURE TRANSIENT FIX, naming David Potasek and Roger Backman as inventors, which is incorporated herein by reference in the entirety.

### TECHNICAL FIELD

The present disclosure relates generally to electronic components, and, more particularly, to asymmetric thermal management of electronic components.

### BACKGROUND OF THE INVENTION

Electronic systems, particularly those involving sensitive components such as sensors, often suffer from accuracy errors during temperature transient conditions. These errors can significantly impact the performance and reliability of devices, leading to decreased production yields and difficulties in meeting customer commitments. For example, in pressure sensors, even single-digit micro-Volt errors can be detrimental.

### SUMMARY

A system for reducing electromotive force (EMF) errors is disclosed in accordance with one or more illustrative embodiments of the present disclosure. In one illustrative embodiment, the system includes a circuit component with a plurality of leads soldered to a circuit board. In another illustrative embodiment, the system includes a filler material coupled to at least a first lead of the plurality of leads. In another illustrative embodiment, the system exhibits an asymmetrical thermal conduction of the first lead relative to a different lead of the plurality of leads due to the filler material.

In a further aspect, the asymmetrical thermal conduction is associated with the filler material being selectively coupled to only a subset of the plurality of leads, and not to all of the plurality of leads. In another illustrative embodiment, the asymmetrical thermal conduction is associated with the filler material including an internal asymmetrical thermal conduction profile across the filler material from the first lead relative to the different lead, and the filler material is coupled to both the first lead and the different lead. In another illustrative embodiment, the internal asymmetrical thermal conduction profile of the filler material is associated with a difference in porosity of the filler material between the first lead and the different lead. In another illustrative embodiment, the internal asymmetrical thermal conduction profile of the filler material is associated with a difference in a first amount of the filler material coupled to the first lead relative to a second amount of the filler material coupled to the different lead. In another illustrative embodiment, the asymmetrical thermal conduction of the filler material is associated with a difference of the filler material including a first filler material coupled to the first lead relative to a second filler material coupled to the different lead, where the first filler material is different than the second filler material, and the first filler material includes a different heat capacity and different thermal conductivity relative to the second filler material.

In another illustrative embodiment, the plurality of leads includes a plurality of output leads of the circuit component, and the filler material is selectively coupled to at least one but less than all of the plurality of output leads. In another illustrative embodiment, the circuit component includes a sensor. In another illustrative embodiment, the sensor includes a micro-electromechanical systems (MEMS) sensor. In another illustrative embodiment, the MEMS sensor includes a pressure sensor. In another illustrative embodiment, the filler material includes an epoxy.

In a further aspect, due to at least one of: an active operation of the circuit board or due to an external environment outside the circuit component, a first area of the circuit board coupled to the first lead is configured to transfer a different amount of thermal energy relative to a second area of the circuit board, where a respective amount of the filler material coupled to each respective lead is proportional to a respective amount of the thermal energy that is configured to be transferred by the respective lead. In another illustrative embodiment, the system includes a conformal coating coupled to the plurality of leads, where the conformal coating is disposed between the plurality of leads and the filler material. In another illustrative embodiment, the filler material is disposed between the plurality of leads and the conformal coating.

A method is disclosed in accordance with one or more illustrative embodiments of the present disclosure. In one illustrative embodiment, the method may include tuning a circuit component of a system. In another illustrative embodiment, the system may include the circuit component comprising a plurality of leads. In another illustrative embodiment, the circuit component is coupled to a circuit board. In another illustrative embodiment, the tuning of the circuit component may include receiving thermal energy data of the circuit board comprising the circuit component with the plurality of leads coupled to the circuit board. In another illustrative embodiment, the method may include identifying, based on the thermal energy data, at least a first lead of the circuit component, where the at least the first lead is configured to receive asymmetrical thermal energy relative to a different lead. In another illustrative embodiment, the method may include applying filler material to the at least the first lead based on the identification such that the system includes an asymmetrical thermal conduction of the first lead relative to the different lead due to the filler material.

In a further aspect, the plurality of leads may include a plurality of output leads of the circuit component, where the filler material is selectively coupled to at least one but less than all of the plurality of output leads.

A method is disclosed in accordance with one or more illustrative embodiments of the present disclosure. In one illustrative embodiment, the method may include fabricating a system. In another illustrative embodiment, the system may include a circuit component comprising a plurality of leads. In another illustrative embodiment, the circuit component is coupled to a circuit board. In another illustrative embodiment, a filler material is coupled to at least a first lead of the plurality of leads. In another illustrative embodiment, the system may exhibit asymmetrical thermal conduction of the first lead relative to a different lead of the plurality of leads due to the filler material. In another aspect, the fabricating of the system may include receiving thermal energy data of the circuit board including the circuit component with the plurality of leads coupled to the circuit board. The thermal energy data corresponds to at least one of an active operation of the circuit board or due to an external environment outside the circuit component. In another aspect, the method may include identifying, based on the thermal energy data, the at least the first lead of the circuit component, where the at least the first lead is configured to receive asymmetrical thermal energy relative to a different lead. In another aspect, the method may include applying the filler material to the at least the first lead based on the identification of the at least the first lead such that the system exhibits the asymmetrical thermal conduction of the first lead relative to the different lead.

In a further aspect, the plurality of leads may include a plurality of output leads of the circuit component, where the filler material is selectively coupled to at least one but less than all of the plurality of output leads.

It is to be understood that both the foregoing general description and the following detailed description are exemplary and explanatory only and are not necessarily restrictive of the present disclosure. The accompanying drawings, which are incorporated in and constitute a part of the characteristic, illustrate subject matter of the disclosure. Together, the descriptions and the drawings serve to explain the principles of the disclosure.

### BRIEF DESCRIPTION OF THE DRAWINGS

The detailed description is described with reference to the accompanying figures. The use of the same reference numbers in different instances in the description and the figures may indicate similar or identical items. Various embodiments or examples (“examples”) of the present disclosure are disclosed in the following detailed description and the accompanying drawings. The drawings are not necessarily to scale. In general, operations of disclosed processes may be performed in an arbitrary order, unless otherwise provided in the claims.

FIG. 1 is an electronic component with staking material.

FIG. 2 is a simplified diagram illustrating a system for reduced error that includes epoxy on a lead, in accordance with one or more embodiments of the present disclosure.

FIG. 3 is a system with epoxy on all leads, in accordance with one or more embodiments of the present disclosure.

FIG. 4 is a circuit component with leads having different materials that may be prone to generating EMF during temperature transient conditions, in accordance with one or more embodiments of the present disclosure.

FIG. 5 is a flow diagram illustrating steps performed in a method for reduced error, in accordance with one or more embodiments of the present disclosure.

FIG. 6 is a diagram of a reduction in transient sensor error corresponding to using a filler material, in accordance with one or more embodiments of the present disclosure.

### DETAILED DESCRIPTION

Reference will now be made in detail to the subject matter disclosed, which is illustrated in the accompanying drawings.

Before explaining at least one embodiment of the inventive concepts disclosed herein in detail, it is to be understood that the inventive concepts are not limited in their application to the details of construction and the arrangement of the components or steps or methodologies set forth in the following description or illustrated in the drawings. In the following detailed description of embodiments of the instant inventive concepts, numerous specific details are set forth in order to provide a more thorough understanding of the inventive concepts. However, it will be apparent to one of ordinary skill in the art having the benefit of the instant disclosure that the inventive concepts disclosed herein may be practiced without these specific details. In other instances, well-known features may not be described in detail to avoid unnecessarily complicating the instant disclosure. The inventive concepts disclosed herein are capable of other embodiments or of being practiced or carried out in various ways. Also, it is to be understood that the phraseology and terminology employed herein is for the purpose of description and should not be regarded as limiting.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the inventive concepts disclosed herein in any way unless expressly stated to the contrary.

In addition, use of the “a” or “an” are employed to describe elements and components of embodiments of the instant inventive concepts. This is done merely for convenience and to give a general sense of the inventive concepts, and “a” and “an” are intended to include one or at least one and the singular also includes the plural unless it is obvious that it is meant otherwise.

Further, unless expressly stated to the contrary, “or” refers to an inclusive or and not to an exclusive or. For example, a condition A or B is satisfied by anyone of the following: A is true (or present) and B is false (or not present), A is false (or not present) and B is true (or present), and both A and B are true (or present).

Further, any arrangement of components to achieve a same functionality is effectively “associated” such that the desired functionality is achieved, such that any two components herein combined to achieve a particular functionality can be seen as “associated with” each other (irrespective of architectures or intermedial components). Any two components so associated can also be viewed as being “operably connected” or “operably coupled” to each other to achieve the desired functionality, and any two components capable of being so associated can also be viewed as being “operably couplable” to each other to achieve the desired functionality. Examples of operably couplable include, but are not limited to, physically mateable and/or physically interacting components, wirelessly interactable and/or wirelessly interacting components, logically interacting and/or logically interactable components, or the like.

Further, one or more components may be referred to herein as “configured to,” “configurable to,” “operable/operative to,” “adapted/adaptable,” “able to,” “conformable/conformed to,” etc. Those skilled in the art will recognize that such terms (e.g., “configured to”) can generally encompass active-state components and/or inactive-state components and/or standby-state components, unless context requires otherwise.

Finally, as used herein any reference to “one embodiment,” or “some embodiments” means that a particular element, feature, structure, or characteristic described in connection with the embodiment is included in at least one embodiment of the inventive concepts disclosed herein. The appearances of the phrase “in some embodiments” in various places in the specification are not necessarily all referring to the same embodiment, and embodiments of the inventive concepts disclosed may include one or more of the features expressly described or inherently present herein, or any combination of sub-combination of two or more such features, along with any other features which may not necessarily be expressly described or inherently present in the instant disclosure.

Due to physics, a temperature change of different materials in leads/pins of a circuit component can cause a voltage difference. That generation of voltage may be referred to as a thermally induced electromotive force (EMF) and it may cause errors in the readings of the circuit component, such as erroneous sensor readings. The thermally induced EMF may also be referred to as, at least for purposes of the present disclosure, a thermoelectric effect, a Seebeck EMF, a Seebeck Voltage, thermocouple EMF, thermocouple voltage, or the like.

Broadly speaking, the present disclosure is directed to using filler material (e.g., epoxy, gaskets) to reduce errors of circuit components caused by temperature transient conditions.

By adding filler material, the Seebeck coefficient of these leads is not necessarily modified, but rather the magnitude of the temperature gradient across the leads are modified and the EMF noise is reduced. The leads of a circuit component may still be sensitive in temperature under the filler material. However, in a sense, the filler material may reduce the change in temperature that the lead is experiencing by wrapping the lead in a thermally conductive coat that transfers some of the heat and does some of the work of thermal energy transfer.

The filler material, in a sense, may allow for counteracting and/or compensating for the thermally induced EMF. For example, the filler material may be selectively applied to some leads and not others. Alternatively, and/or in addition, the filler material may provide differential insulating properties to different leads by different amounts of porosity, different material properties such as thermal conductivity and heat capacity, and/or different amounts of the filler material applied to different leads or any other method of differential insulating properties such as filler with directionality (e.g., non-isotropic material such as polarized material).

Thermal energy in the system may affect some leads more than others. For example, different material in the leads may be more susceptible to temperature gradients, and/or different leads may be positioned so as to experience more temperature gradients than other leads such as being located in or near a hot spot. A circuit component may generate its own heat asymmetrically or be near a component that asymmetrically heats different areas of the circuit board differently. Without the filler material, a circuit component may be near an edge of the aircraft (or other factor that causes temperature differences) and some leads of the circuit component may experience temperature changes sooner than others due to differences in convective, conductive, and/or radiative heat. Materials (e.g., copper, aluminum, etc.) of each lead itself theoretically heat at different rates and/or each lead may include different materials and/or different amounts of each material. It is contemplated herein that these differences in materials and/or differences in various factors affecting how the leads transfer thermal energy over time during changing temperatures (e.g., temperature transience) may affect an amount of thermally-induced electromotive force (EMF) generated in each lead. Circuit components can be highly sensitive with error budgets within single-digit micro-Volts and can be negatively affected by the EMF generated by transient temperatures.

It is contemplated herein that a filler material may compensate for these differences and reduce differences in EMF between difference leads or reduce EMF in all leads or the like, and thereby improve the operation (e.g., pressure sensor accuracy) of a circuit component.

The system herein may be any system. For example, the system may include precision sensors, such as precision pressure sensors used in aerospace applications for air data or engine control.

It is noted herein that some precision sensor systems may suffer accuracy errors under temperature transient conditions. This type of issue may significantly affect production yields. The error budget may be strict for circuit components (e.g., sensors) of such systems, such as an error budget in the range of single-digit micro-Volts.

It is contemplated herein that a significant factor causing a failure of a system was found to be unbalanced thermoelectric effects of the various conductors of a channel of a circuit component. The role of each of many building blocks were investigated, such as, but not necessarily limited to: packaging variation, wire bonding; interactions of a MEMS sensor including solder variation, lead/barrel placement, polyurethane (conformal coating), and conductive paste. It was found that applying an asymmetrical thermal path (e.g., selectively applying epoxy) to a location (e.g., the most sensitive location), that temperature transient error of a circuit component (e.g., sensor) could be controlled.

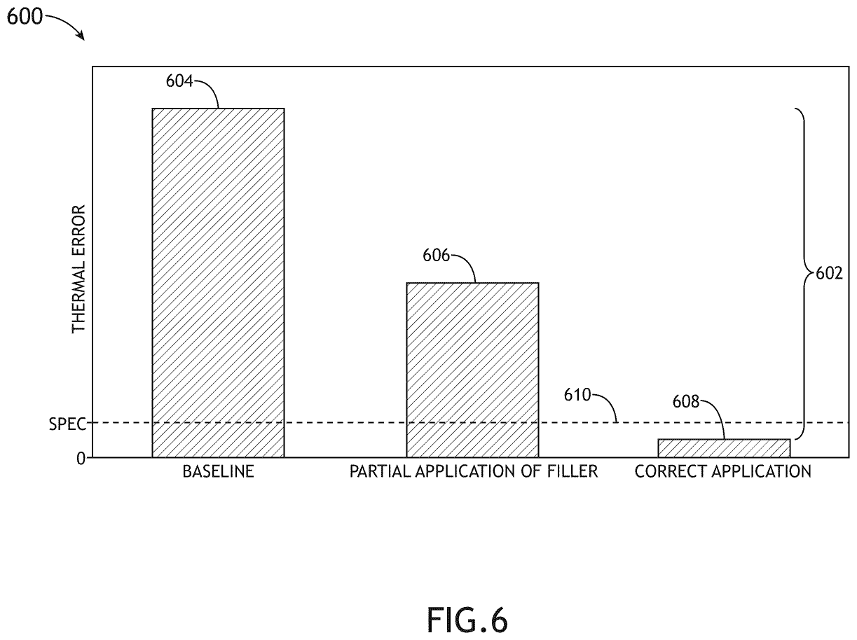

Such issues have occurred for decades in such systems without an adequate solution. See FIG. 6 for an illustration of how the solution of the present disclosure addresses this longstanding issue. Note that the data in FIG. 6 is simplified for purposes of clarity but is derived from multiple test samples.

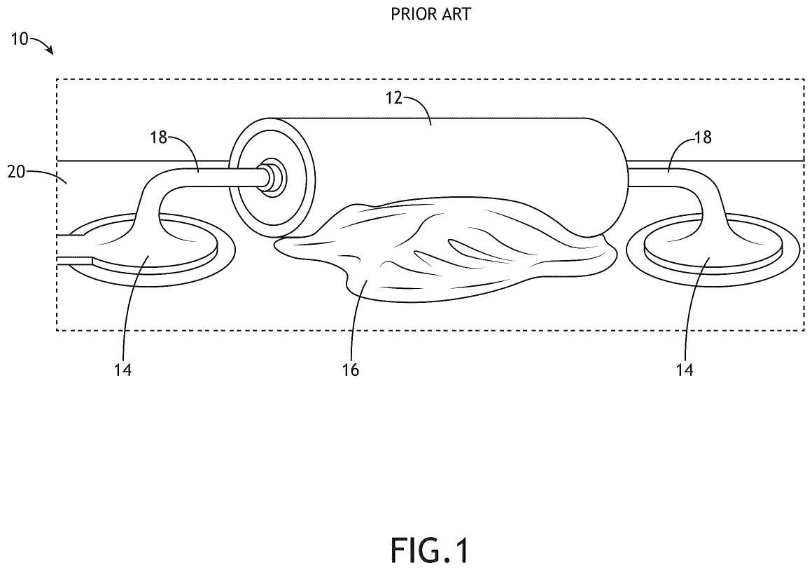

FIG. 1 illustrates an electronic component 12 with staking material 16.

In conventional systems 10, staking material 16 may be used. For example, an electronic component 12 with leads 18 may be soldered with solder material 14 to a circuit board 20. Then, staking material 16 may be used to help provide mechanical support for the electronic components 12 during normal operations. For example, NASA-STD-8739.1B, a NASA Technical Standard entitled WORKMANSHIP STANDARD FOR POLYMERIC APPLICATION ON ELECTRONIC ASSEMBLIES, approved on Jun. 30, 2016 explains a method of using staking material.

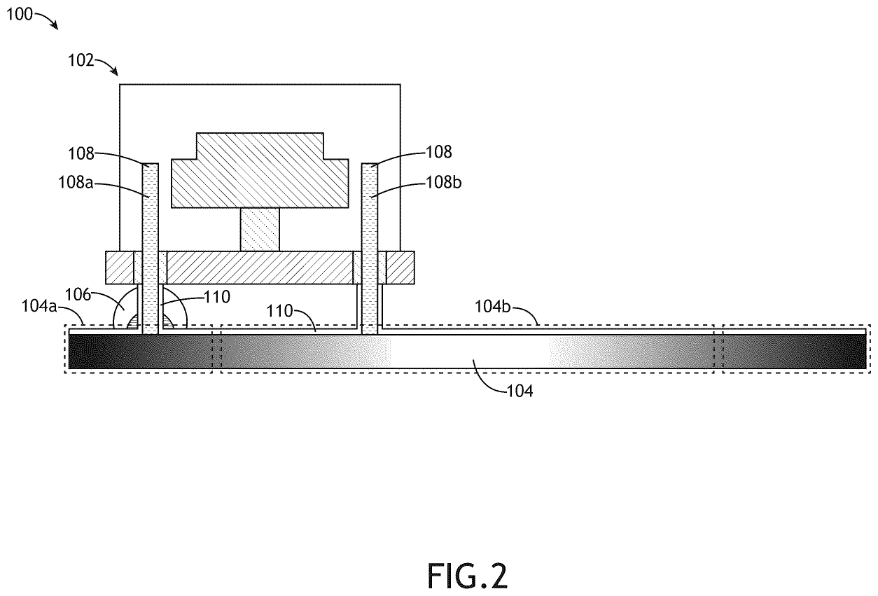

FIG. 2 illustrates a simplified diagram showing a side view of a system 100 for reduced error that includes filler material 106 on a lead 108 (e.g., pin), in accordance with one or more embodiments of the present disclosure.

The system 100 may include the circuit component 102. The circuit component 102 may include a plurality of leads 108 coupled (e.g., soldered) to a circuit board 104. For example, the system 100 may be or include an electronic sub-system of an aircraft. For instance, the system 100 may be any sub-system of an aircraft, such as a precision sensor system, a line-replaceable unit (LRU) and/or a sensor sub-system configured to sense internal and/or external attributes (e.g., temperature, pressure, and/or the like).

The system 100 may include a filler material 106. The filler material 106 may be coupled to at least a first lead 108a of the plurality of leads 108. The first lead 108a may be any lead, not necessarily a lead in a first position. Rather, “first” is used for distinction purposes from other leads only.

A yield of the system 100 in a production line environment may be increased by using the filler material 106, saving costs. The accuracy (e.g., pressure accuracy of a pressure sensor component) may be improved by using the filler material 106.

The system 100 may include an asymmetrical thermal conduction associated with the first lead 108a relative to a different lead 108b of the plurality of leads 108. In other words, the combination of the filler material 106 and first lead 108a, as a combined whole, may have different thermal conduction properties compared to the thermal conduction properties of the different lead 108b. This doesn't necessarily mean the different lead 108b doesn't have filler material 106, but that the combination of the different leads 108b with respective filler material 106 or without any filler material has different thermal conduction properties. For example, more porosity, an alternative filler material, or more or less filler material 106 may be used on the different leads 108b compared to the first lead 108a—or no filler material 106 could be used. For instance, the filler material 106 may be applied to a single lead 108.

The magnitude of a thermal gradient across the length of a lead 108 will generate a thermally induced electromotive force, via the Seebeck effect. The thermal conduction in and around a first lead 108a may be altered or induced by the filler material 106. For example, the filler material 106 may alter the thermal gradient affecting the first lead 108a. For instance, the filler material 106 may reduce how much a thermal gradient affects the first lead 108a, compared to no filler material. In this way, the filler material 106 may provide modified thermal properties to select leads.

Consider a scenario where one or more leads 108 heat up faster due to asymmetrical thermal heating of the circuit board 104 or due to variations/imbalances in ambient heating. A method may include measuring the asymmetrical thermal heating of the circuit board 104 and applying filler material 106 to the one or more leads 108 that heat up the fastest. After applying filler material 106, the heating of the one or more leads 108 compared to the other (uninsulated) leads may be more uniform over time. This may reduce the thermally induced EMF of the leads and thereby improve the operation of the circuit component.

The asymmetrical thermal conduction may be associated with the filler material 106 being selectively coupled to only a subset of the plurality of leads 108, and not to all of the plurality of leads 108. In other words, some of the leads 108 may not receive any filler material. For example, as shown in FIG. 2, first lead 108a has filler material 106 applied, and a different lead 108b does not have filler material applied.

The circuit component 102 may include (or be) a sensor. For example, the sensor may include a micro-electromechanical systems (MEMS) sensor. For instance, the micro-electromechanical systems (MEMS) sensor may include a pressure sensor. However, note that these examples are non-limiting and a variety of components, such as a variety of sensors may be used. For instance, the sensor may include at least one of a temperature sensor, or a pressure sensor.

The filler material 106 may include a single material, or more than one material. For example, the filler material 106 may be made from different materials, varied porosity of a single material, different alignment of non-isotropic materials, different amounts applied, and/or the like to achieve asymmetric thermal conduction between various leads.

For example, the filler material 106 may include (or be) a material with different thermal conductivity than the leads 108. In at least some embodiments, the filler material 106 is thermally conductive. For example, the filler material 106 may have a thermally conductivity of at least 0.5 W/m*K (Watts per meter-kelvin).

For example, the filler material 106 may include (or be) a thermally conductive encapsulant. The filler material 106 may be a paste with high thermal conductivity. For instance, the thermal conductivity of the filler material 106 may be higher than the thermal conductivity of the leads 108. Either high conductive or low thermal conductive encapsulants may be used depending on the needs of the application.

For example, the filler material 106 may include (or be) an epoxy. The filler material 106 may be a silicone.

The epoxy may include (or be) a room temperature vulcanizing (RTV) epoxy or temperature cured epoxy. Epoxies have formulations with various thermal conductivities.

For example, the filler material 106 may include (e.g., have) directionality. For instance, the filler material 106 may include (or be) non-isotropic material such as polarized material.

The filler material 106 may include (or be) a gasket.

The filler material 106 may be electrically insulative (i.e., not electrically conducting).

The filler material 106 may be applied above and/or below a conformal coating 110 of the system 100. For example, a pre-determined amount of filler material 106 may be disposed. For example, the filler material 106 may be applied after (and on top of) the conformal coating 110, such as calibrating an amount of filler material 106 to use based on a measured thermal asymmetry of the circuit component 102 and/or circuit board 104. Conformal coatings may be used as protective chemical coatings that conform to the contours of electronic components, providing a protective barrier against environmental contaminants such as moisture, dust, chemicals, and temperature extremes. Conformal coatings are typically applied as a thin film, and their purpose may include improving the reliability and longevity of electronic assemblies by preventing corrosion and electrical failures. Conformal coatings may have relatively high dielectric strength, thermal stability, and structural flexibility. Conformal coatings may include, but are not necessarily limited to, acrylics, polyurethanes, and silicones. For example, polyurethane coatings may be used for their chemical resistance properties.

Typically, applying staking material 16 such as is shown in FIG. 1 is performed before applying a conformal coating. However, at least some embodiments of the present disclosure include at least some filler material 106 applied after the conformal coating 110. For example, the system 100 may include a conformal coating 110 coupled to the plurality of leads 108. For example, the conformal coating 110 may be disposed between the plurality of leads 108 and the filler material 106.

Further, some methods may apply filler material 106 before the conformal coating 110. The filler material 106 may be disposed between the plurality of leads 108 and the conformal coating 110. For example, in new circuit boards, it may already be known how much filler material 106 is going to be used or an initial estimate of filler material 106 may be used under the conformal coating and a fine-tuned amount of filler material 106 may be used on top of the conformal coating after testing each component. This may be referred to as a fine-tuning of filler material.

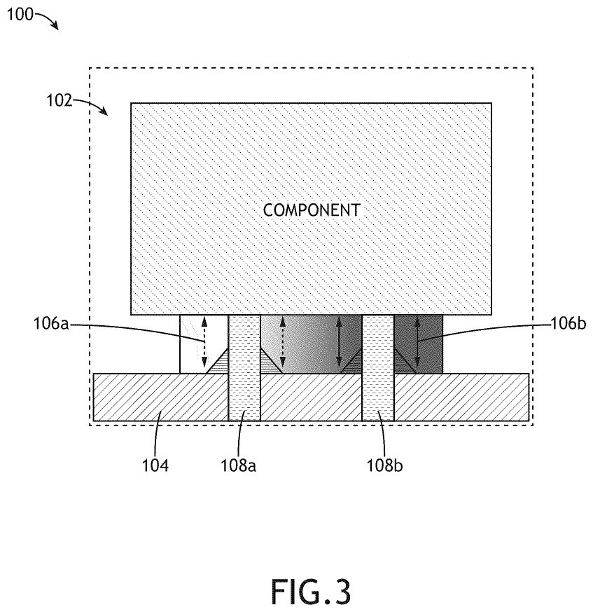

Referring to various areas 104a, 104b of the circuit board 104, the filler material 106 may compensate for errors caused by asymmetrical thermal heating of such areas. A respective amount of the filler material 106 coupled to each respective lead 108 may be proportional to a respective amount of thermal energy that is configured to be transferred by the respective lead 108 due to at least one of: an active operation of the circuit board or due to an external environment outside the circuit component. Due to an active operation of the circuit board 104, such as turning on electricity provided to the circuit board 104, a first area 104a of the circuit board 104 coupled to the first lead 108a may be configured to transfer (and/or generate) a different amount of thermal energy relative to a second area 104b of the circuit board 104. For instance, some components on the circuit board 104 may run hotter than others. The first area 104a may transfer more thermal energy during a typical operation of the circuit board 104. As shown in FIG. 3, applying a first amount of filler material 106a and a second amount of filler material 106b to such areas 104a, 104b, respectively, may reduce errors of the circuit component 102 otherwise caused by asymmetrical heating of different leads. The amounts of filler material 106a, 106b may be proportional to a respective amount of thermal energy that is configured to be transferred by corresponding respective leads 108a, 108b.

FIG. 3 illustrates a system 100 with epoxy on all leads 108, in accordance with one or more embodiments of the present disclosure.

The filler material 106 may have an internal asymmetrical thermal conduction profile across the filler material 106 from the first lead 108a relative to the different lead 108b. For example, as shown in FIG. 3, the filler material 106 may be coupled to both the first lead 108a and the different lead 108b, and/or all of the leads. In some examples, some of the leads 108a may have more amounts of filler material 106 (and/or more porosity in corresponding filler material 106 near respective leads 108) than other leads 108. For instance, for more porosity, the filler material 106 may be foamed more or less for more or less density. The more porous, then the more thermally insulative the filler material 106 may be. The profile of the internal asymmetrical thermal conduction profile is the measurable amount of thermal conduction at different locations of the filler material 106 itself. For example, having different porosity associated with different thermal conductivity along the length of the filler material 106 shown in FIG. 3 means the internal thermal conduction profile is asymmetrical.

As noted, the internal asymmetrical thermal conduction profile of the filler material 106 may be associated with a difference in porosity of the filler material 106 between the first lead 108a and the different lead 108b. For instance, as shown in FIG. 3, although not necessarily, the filler material 106 may be applied, continuously, across the first lead 108a and the different lead 108b, rather than applied individually.

The internal asymmetrical thermal conduction of the filler material 106 may be associated with a difference in a first amount of the filler material 106 coupled to the first lead 108a relative to a second amount of the filler material 106 coupled to the different lead 108b. For example, a thicker/greater amount of the filler material 106 may be applied to some of the leads 108 more than other leads 108. A first filler material 106a with one set of material properties may be applied to the first lead 108a and a second filler material 106b with distinct material properties may be applied to the second lead 108b. For example, the first filler material 106a and the second filler material 106b may have different thermal conductivity properties. This may be another method of regulating the thermal conductivity properties of the leads 108. Any of the methods herein, unless otherwise specified, may be combined. For example, some leads 108 may include filler material 106 and some may not, while simultaneously some leads may be coupled to larger amounts of filler material 106 and/or differences in porosity of the filler material 106. Knowing which methods to use may depend on the cost, reliability, controllability as well as the type of particular component 102 being insulated and how much insulation is needed.

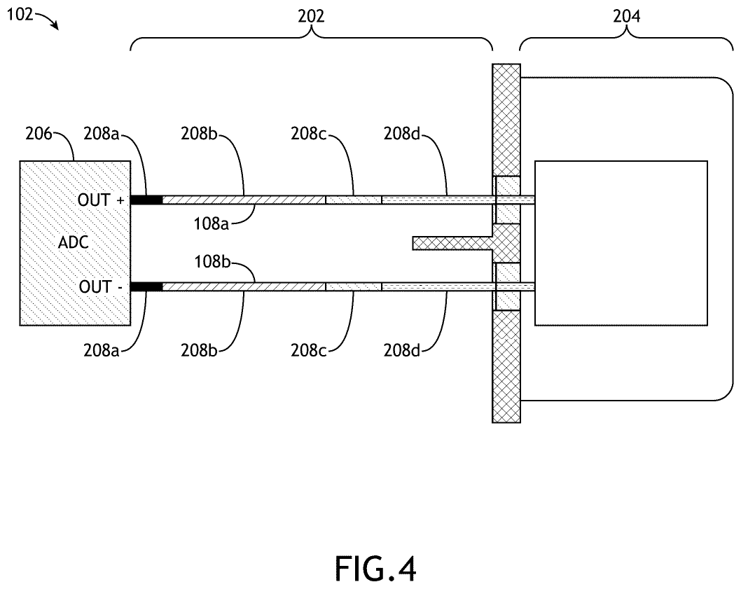

FIG. 4 illustrates a circuit component 102 with leads 108a, 108b having different materials 208a, 208b, 208c, 208d that may be prone to generating EMF during temperature transient conditions, in accordance with one or more embodiments of the present disclosure.

The plurality of leads 108 may include a plurality of output leads of the circuit component 102. The filler material 106 may be selectively coupled to at least one but less than all of the plurality of output leads 108. For example, circuit components 102 sometimes comprise input leads and output leads. It is contemplated herein that applying the filler material 106 to output pins in particular, in some embodiments, may provide improvement. For example, a pressure sensor circuit component 102 may include output leads 108 (e.g., output pins), with the filler material 106 applied/coupled to one or more of those output leads 108. This may mean that none of the input pins include filler material.

An upper portion 204 may be the sensor configured to sense a parameter such as pressure, temperature, or the like. The lower portion 202 may be portions of leads 108a, 108b protruding below the circuit board.

The system may include an analog-to-digital converter (ADC) 206 coupled to the output leads 108.

The first lead 108a of the plurality of leads 108 may include a set of sequentially coupled different materials 208a, 208b, 208c, 208d along a length of the first lead 108a.

For example, the circuit component 102 may be (or include) a pressure sensor circuit component 102. The pressure sensor circuit component 102 may include a first lead 108a including a set of sequentially coupled different materials 208a, 208b, 208c, 208d. For instance, a set of sequentially coupled different materials 208a, 208b, 208c, 208d may include a material comprising copper, a solder material (e.g., material comprises lead configured to be used as solder), and a different material comprising metal (e.g., kovar pin material), respectively. Such materials may heat at different rates. For example, in such a lead 108, most of the inaccuracies might be caused by a kovar pin material and the solder material.

In an optional step, a choice of the filler material 106 may be selected based on the material of the leads 108. A property of a material is the Seebeck coefficient. If a temperature gradient exists over a piece of electrically conductive material (e.g., lead 108), then there is a net diffusion of electrons from the hot end toward the cold end, thereby creating an opposing electric field. When the filler material is conductive and in electrical contact with the lead 108 the Seebeck coefficient of the filler can change the lead's thermoelectric effect. The Seebeck coefficient of the filler material 106 may be selected to be zero or near zero (e.g., within 10 microvolts per kelvin (uV/K) of 0). Alternatively, the Seebeck coefficient of the filler material 106 may be selected to be near zero, zero, or positive when the Seebeck coefficient of the lead 108 is negative (e.g., (relatively highly negative). For example, the filler Seebeck coefficient of filler material 106 may be between-10 and positive 10 uV/K when the filler material is coupled to a lead 108 having material (e.g., kovar pin material 208d) with a Seebeck coefficient less than-15 V/K.

It should be noted that any number of the descriptions and limitations described in the present disclosure may be combined. For example, in one embodiment of a system 100 the following may all occur: the plurality of leads 108 may include a plurality of output leads of the circuit component 102; the filler material 106 may be selectively coupled to at least one but less than all of the plurality of output leads 108; the plurality of output leads 108 may include the first lead 108a; the filler material 106 may include an epoxy; the circuit component 102 may include a pressure sensor; and the first lead 108a of the plurality of leads 108 may include a set of sequentially coupled different materials 208a, 208b, 208c, 208d along a length of the first lead 108a.

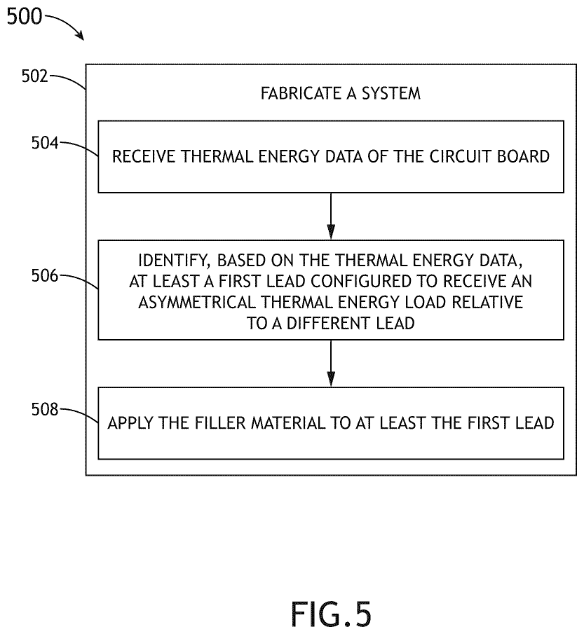

FIG. 5 illustrates a flow diagram illustrating steps performed in a method 500 for reduced error, in accordance with one or more embodiments of the present disclosure. At step 502, a system 100 is fabricated.

The system 100 may include various components such as a circuit component 102, a circuit board 104, and a plurality of leads 108. The system 100 may include a circuit component 102 and a filler material 106. The circuit component 102 may include a plurality of leads 108 soldered to a circuit board 104. The filler material 106 may be coupled to at least a first lead 108a of the plurality of leads 108. The system 100 may include an asymmetrical thermal conduction of the first lead 108a relative to a different lead 108b of the plurality of leads 108 due to the filler material 106.

The fabricating step 502 of the system 100 may include at least steps 504, 506, and 508.

At step 504, thermal energy data of the circuit board 104 is received. For example, the thermal energy data may be temperature readings received by a person or a controller including a memory and processor. The thermal energy data may correspond to an electrical operation of the circuit board 104. For example, the thermal energy data may include temperature readings (e.g., Fahrenheit, Celsius, Kelvin) at various points of the system 100. For example, the points may be on the leads 108, on the circuit board 104 near (e.g., within 2 millimeters) of the leads 108, and/or the like. These readings may be taken over time during a temperature transient condition. For instance, the temperature of the circuit board 104 and/or ambient air temperature may be changed, or the like. For instance, the circuit board 104 may be electrically operated (e.g., turning on processors, circuit components, and the like) and the electrical operation may change the temperature of various areas of the circuit board 104. In some embodiments, the thermal energy data may be simulated (e.g., estimated based on the type and location of components) and/or based on historical data (e.g., historical data of similar or identical circuit boards).

At step 506, the fabricating of the system 100 may include identifying, based on the thermal energy data, at least the first lead 108a of the circuit component 102. For example, the first lead 108a may include one or more leads 108 configured to receive asymmetrical thermal energy relative to a different lead. For instance, the first lead 108a may heat up faster than different leads. For example, the first lead 108a may include leads 108 where the temperature, and/or thermal absorption rate (e.g., thermal conductivity or the like) is above a threshold, outside a standard deviation compared to other leads, and/or the like. For instance, a formula that identifies leads 108 that have a different temperature measurement outside a threshold (e.g., more than 1 degree Celsius difference) at any point in time compared to other leads during operation of the circuit board 104 (without filler material) may be used to make a determination of which leads should receive filler material 106.

At step 508, the fabricating of the system 100 may further include applying the filler material 106 to at least the first lead 108a. This may be based on the identification of at least the first lead 108a. For example, all leads 108 outside the threshold may be identified and then have filler material 106 applied to them. As a result, the system 100 may now have asymmetrical thermal conduction of the first lead 108a relative to the different lead 108b. The amount of filler material 106 used for each identified lead 108 may be proportional to thermal energy data associated with the respective lead. For example, the amount of filler material 106 used for each identified lead 108 may be proportional to the measured differences in temperature between the leads 108, where hotter leads get more filler material 106. The amount of filler material 106 used for each identified lead 108 may be proportional to material properties of the lead, such as Seebeck coefficients of materials in the lead 108.

The filler material 106, if it includes or is an epoxy, may be cured.

The fabricating step 502 may be used to make new circuit boards 104.

The fabricating step 502 may also be used for correcting circuit boards 104 without replacing circuit components 102. For example, the method may include a step of receiving existing circuit boards (e.g., circuit board 104) and operating the circuit board 104 and measuring thermal energy data. For instance, the filler material 106 may be applied to at least a first lead 108a of the existing circuit board 104. In this way, sensors (e.g., pressure sensors) of a circuit board 104 may be improved, such as fine-tuning, fixing, increasing sensor accuracy, and/or the like.

In embodiments, the fabricating step 502 may include (or be) a tuning of a circuit board 104. In this sense, the fabricating step 502 may be referred to as a tuning step 502. For example, the fabricating of the system 100 may be a tuning (e.g., fine-tuning) of the system 100 configured to determine how much filler material 106 to apply to match more or less variation in thermally induced EMF due to variation in manufacturing processes. For instance, this tuning may be different than applying a same amount each time, but rather an amount may be identified to exactly or near exactly cancel the thermally induced EMF for each specific unit fabricated.

As noted above, conventionally, conformal coatings are typically applied last, or nearly last, to a circuit board. In one or more embodiments of the present disclosure, filler material 106 may be applied on top of a conformal coating, such as during a tuning step 502.

FIG. 6 illustrates a diagram 600 of a reduction 602 in transient sensor error values 604, 606, 608 corresponding to using a filler material 106, in accordance with one or more embodiments of the present disclosure.

The baseline value 604 is without any filler material. The baseline value 604 is highest, showing the most transient temperature error corresponding to a difference between actual sensor readings and measured sensor readings during a transient temperature. To achieve a transient temperature, the sensors may be placed in a heating apparatus, such as an oven.

The goal of the test was to reduce the transient temperature error below a threshold value 610.

The partial application value 606 shows a reduced transient temperature and corresponds to a partial application of the filler material 106.

The last transient temperature error values 608 correspond to an amount of filler material 106 sufficient to stay below the threshold value 610.

The units of the transient sensor error values 604, 606, 608 may be pressure error per change in temperature per ° C. of test system ramp rate. For example, the units may be of the form:

ΔP*/(ΔT*(° C./min)) (Eq. 1)

where ΔP represents the change in pressure, ΔT represents the change in temperature, and ° C./min indicates the rate at which the temperature is varied in degrees Celsius per minute. This unit reflects how much the pressure measurement error varies with the rate of temperature change, allowing for a quantitative comparison of sensor performance under different transient thermal conditions.

In a general sense, those skilled in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle;

alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

We claim:

1. A system for reducing electromotive force (EMF) errors, comprising:
a circuit component comprising a plurality of leads soldered to a circuit board; and
a filler material coupled to at least a first lead of the plurality of leads,
wherein the system comprises an asymmetrical thermal conduction of the first lead relative to a different lead of the plurality of leads due to the filler material.

2. The system of claim 1, wherein the asymmetrical thermal conduction is associated with the filler material being selectively coupled to only a subset of the plurality of leads, and not to all of the plurality of leads.

3. The system of claim 1, wherein the asymmetrical thermal conduction is associated with the filler material comprising an internal asymmetrical thermal conduction profile across the filler material from the first lead relative to the different lead, and wherein the filler material is coupled to both the first lead and the different lead.

4. The system of claim 3, wherein the internal asymmetrical thermal conduction profile of the filler material is associated with a difference in porosity of the filler material between the first lead and the different lead.

5. The system of claim 3, wherein the internal asymmetrical thermal conduction profile of the filler material is associated with a difference in a first amount of the filler material coupled to the first lead relative to a second amount of the filler material coupled to the different lead.

6. The system of claim 1, wherein the asymmetrical thermal conduction of the filler material is associated with a difference of the filler material comprising a first filler material coupled to the first lead relative to a second filler material coupled to the different lead, wherein the first filler material includes a different heat capacity and different thermal conductivity relative to the second filler material.

7. The system of claim 1, wherein the plurality of leads comprise a plurality of output leads of the circuit component, wherein the filler material is selectively coupled to at least one but less than all of the plurality of output leads.

8. The system of claim 1, wherein the circuit component comprises a sensor.

9. The system of claim 8, wherein the sensor comprises a micro-electromechanical systems (MEMS) sensor.

10. The system of claim 9, wherein the micro-electromechanical systems (MEMS) sensor comprises a pressure sensor.

11. The system of claim 1, wherein the filler material comprises an epoxy.

12. The system of claim 1, wherein, due to at least one of: an active operation of the circuit board or due to an external environment outside the circuit component, a first area of the circuit board coupled to the first lead is configured to transfer a different amount of thermal energy relative to a second area of the circuit board,
wherein a respective amount of the filler material coupled to each respective lead is proportional to a respective amount of the thermal energy that is configured to be transferred by the respective lead.

13. The system of claim 1,
wherein the plurality of leads comprise a plurality of output leads of the circuit component, wherein the filler material is selectively coupled to at least one but less than all of the plurality of output leads, wherein the plurality of output leads comprises the first lead,
wherein the filler material comprises an epoxy, and
wherein the circuit component comprises a pressure sensor.

14. The system of claim 1, wherein the system comprises a conformal coating coupled to the plurality of leads, wherein the conformal coating is disposed between the plurality of leads and the filler material.

15. The system of claim 1, wherein the system comprises a conformal coating coupled to the plurality of leads, wherein the filler material is disposed between the plurality of leads and the conformal coating.

16. A method for reducing electromotive force (EMF) errors comprising:
tuning a circuit component of a system, wherein the system comprises:
the circuit component comprising a plurality of leads, wherein the circuit component is coupled to a circuit board;
wherein the tuning of the circuit component of the system comprises:
receiving thermal energy data of the circuit board comprising the circuit component comprising the plurality of leads coupled to the circuit board;
identifying, based on the thermal energy data, at least a first lead of the circuit component, wherein the first lead is configured to receive asymmetrical thermal energy relative to a different lead; and
applying filler material to the first lead based on the identifying of the first lead such that the system comprises an asymmetrical thermal conduction of the first lead relative to the different lead due to the filler material.

17. The method of claim 16, wherein the plurality of leads comprise a plurality of output leads of the circuit component, wherein the filler material is selectively coupled to at least one but less than all of the plurality of output leads.

18. The method of claim 16, wherein the circuit component comprises a pressure sensor.

19. A method comprising:
fabricating a system, wherein the system comprises:
a circuit component comprising a plurality of leads, wherein the circuit component is coupled to a circuit board; and
a filler material coupled to at least a first lead of the plurality of leads,
wherein the system comprises an asymmetrical thermal conduction of the first lead relative to a different lead of the plurality of leads due to the filler material,
wherein the fabricating of the system comprises:
receiving thermal energy data of the circuit board comprising the circuit component comprising the plurality of leads coupled to the circuit board, wherein the thermal energy data corresponds to at least one of: an active operation of the circuit board or due to an external environment outside the circuit component;
identifying, based on the thermal energy data, the first lead of the circuit component, wherein the first lead is configured to receive asymmetrical thermal energy relative to the different lead; and
applying the filler material to the first lead based on the identifying of the first lead such that the system comprises the asymmetrical thermal conduction of the first lead relative to the different lead.

20. The method of claim 19, wherein the plurality of leads comprise a plurality of output leads of the circuit component, wherein the filler material is selectively coupled to at least one but less than all of the plurality of output leads.
